(19) United States
(12) Patent Application Publication
(10) Pub. No.: US 2016/0073508 A1
(43) Pub. Date: Mar. 10, 2016

(54) METHOD FOR FORMING METAL PATTERN AND SUBSTRATE HAVING THE SAME

(71) Applicant: Wistron NeWeb Corp., Hsinchu (TW)

(72) Inventors: Tzu-Wen Chuang, Hsinchu (TW); Babak Radi, Hsinchu (TW); Shih-Hong Chen, Hsinchu (TW); Jing-Wen Chen, Hsinchu (TW)

(21) Appl. No.: 14/819,432

(22) Filed: Aug. 6, 2015

(30) Foreign Application Priority Data
Sep. 4, 2014 (TW) 103130611

(51) Int. Cl. H05K 3/18; H05K 1/03; H05K 1/09

(52) U.S. Cl. CPC H05K 3/184; H05K 1/09; H05K 1/0313; H05K 2203/072; H05K 2203/0716; H05K 2203/107

(57) ABSTRACT

A method for forming a metal pattern on a substrate having at least one metal component is provided. By performing the surface passivation treatment on the at least metal component, the surface of the at least metal component becomes an anti-plating surface via an anti-plating coating. Hence, the metal pattern can be selectively formed in the following electroless plating processes.

### CROSS-REFERENCE TO RELATED APPLICATION

This application claims the priority benefit of Taiwan application serial no. 103130611, filed on Sep. 4, 2014. The entirety of the above-mentioned patent application is hereby incorporated by reference herein and made a part of this specification.

### BACKGROUND OF THE INVENTION

1. Field of the Invention

The present invention generally relates to a method for forming a substrate, and also relates to a method for forming a metal pattern.

2. Description of Related Art

Regarding the elements and structures, including circuit board and antenna of the mobile communication devices, the electroless plating process is commonly used to deposit the metal pattern on the surface of the casing or plastic substrate. However, other metal components usually disposed with the plastic substrate, such as metal nuts or metal inserts, may interfere the plating process, so that the undesirable metal plating layer is formed on these metal components or in the unexpected areas during the electroless plating process. Hence, not only the risk of short-circuit is increased, but also the electroless plating solution is wasted and the cost is increased. Besides, it also results in an issue of poor appearance.

Currently, certain anti-plating methods have been proposed to solve the aforementioned problems, for example, by applying a positive voltage to the metal component through the electrode in order to repel the metal ions and avoid the unnecessary electroless plating. However, when the extra voltage is applied, the electroless plating process becomes unstable and the risk of plating out is also increased. Besides, such method requires expensive fixtures, and there should be an opening on the metal component to connect the electrode. Therefore, a convenient and economic anti-plating method is required.

### SUMMARY OF THE INVENTION

The invention provides a substrate having a metal pattern thereon. Through the metal anti-plating treatment, a metal pattern is selectively and regionally formed on the substrate in the electroless plating process, and the metal pattern formed within the predetermined region of the plastic substrate has a precise border.

The invention provides a method of forming a metal pattern for a plastic substrate or a device having at least one metal component thereon. First, the surface passivation treatment is performed to the surface of the metal component of the plastic substrate for anti-plating. Afterwards, laser is used to perform selective activation to the plastic device, and the metal pattern is directly formed in a predetermined region and on the substrate surface by the electroless plating process. The plastic substrate may be any substrate or device having the plastic material and may be a three-dimensional substrate having a plate-shape or a curved surface.

The invention provides a method for forming a metal pattern. First, a substrate having at least one metal component is provided. Next, the surface passivation treatment is performed to the metal component of the substrate. In addition, the laser preliminary treatment is performed to a predetermined region of the substrate to form an activated seed layer. Afterwards, the electroless plating process is performed on the substrate, so that the metal pattern is formed on the activated seed layer within the predetermined region. Besides, it is also possible to perform the surface passivation treatment to treat the metal component firstly, and then place the treated metal component into the plastic substrate. The treated metal component may be placed into the plastic substrate by insert moulding, hot melting or other know technology.

According to an embodiment of the invention, a method for forming a substrate is provided and a substrate including at least one metal component and a metal pattern formed in a predetermined region of the substrate is obtained. The metal component has an anti-plating coating, which is foamed by performing the surface passivation treatment through immersing the metal component of the substrate in an acidic solution. The metal pattern is formed by the subsequent electroless plating process. However, the anti-plating coating is not plated during the electroless plating process.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart showing process steps of a manufacturing process for forming a metal pattern according to an embodiment of the present invention.

FIG. 2A-FIG. 2F are schematic top views showing process steps of a manufacturing process for forming a metal pattern on a substrate according to an embodiment of the present invention.

FIG. 3A-FIG. 3D are schematic cross-sectional views showing process steps of a manufacturing process for forming a metal pattern on a substrate according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The invention provides a method of forming a metal pattern. The metal pattern is to be formed on a plastic substrate or a device having at least one metal component. By processing through a metal anti-plating treatment, the surface of the metal component on the plastic substrate or the device is passivated. Afterwards, a metal pattern is formed on the surface of the plastic substrate or the device by an electroless plating process. No undesirable metal layer will be foamed on the passivated surface of the metal component during the electroless plating process. Hence, a metal pattern with a precise border is formed in a predetermined region of the plastic substrate by electroless plating.

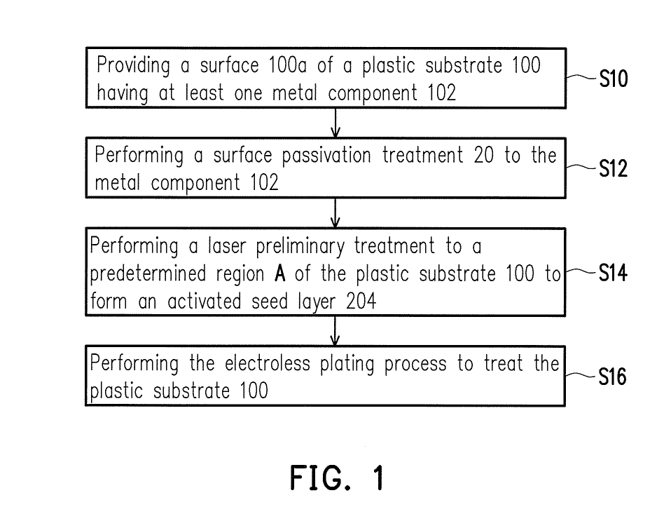

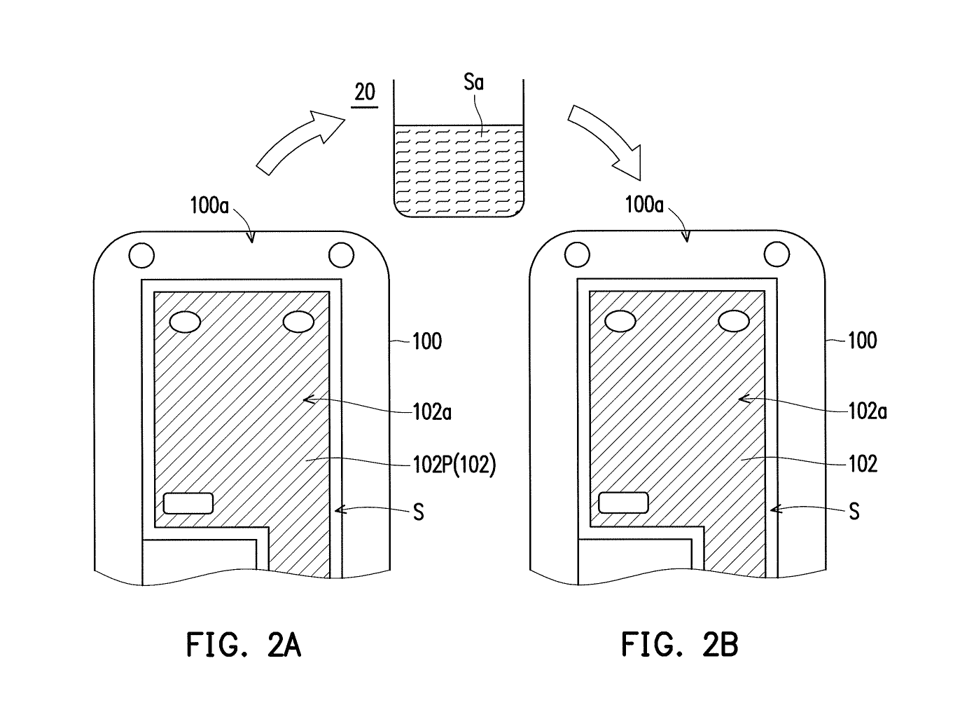

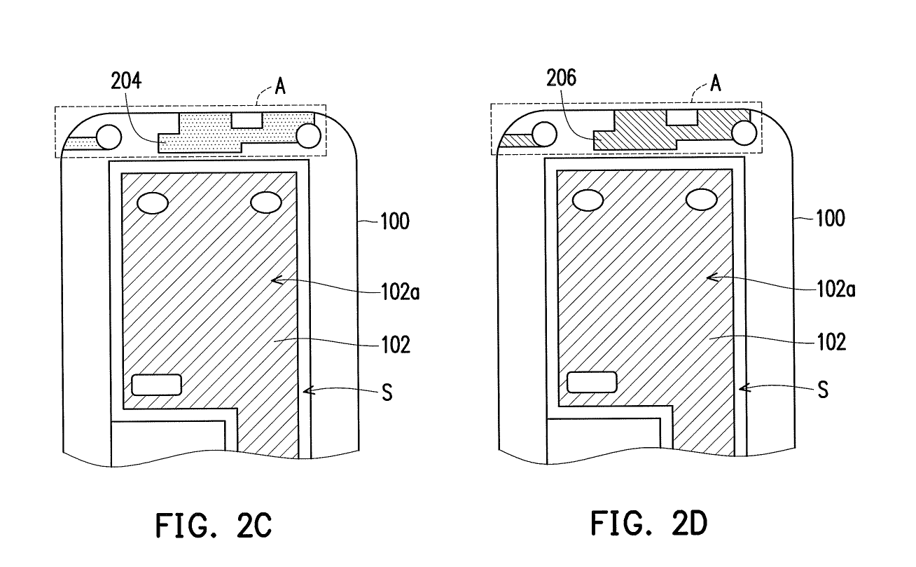

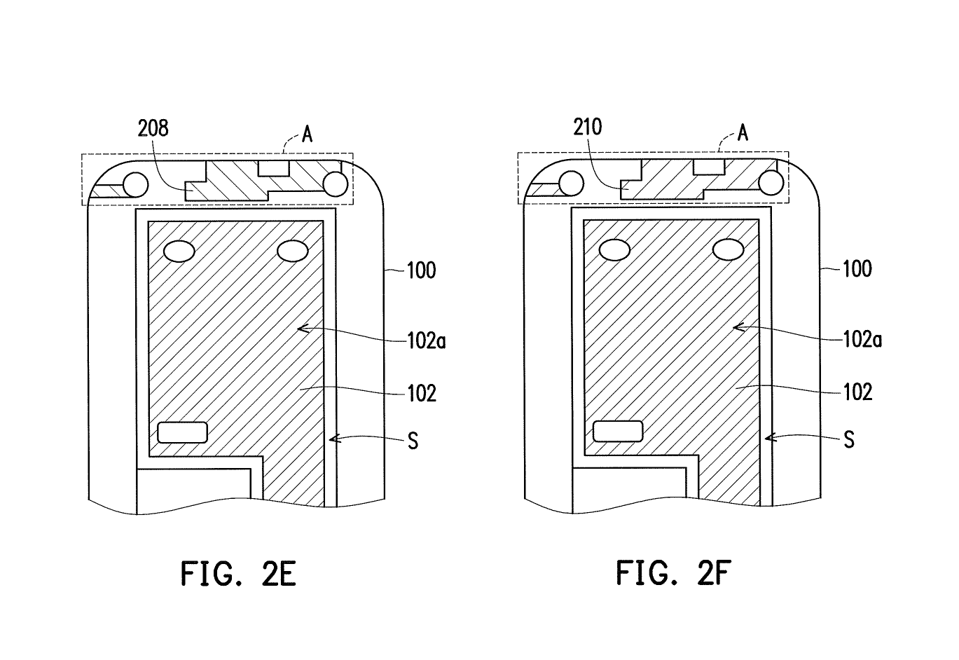

FIG. 1 is a flow chart showing process steps of a manufacturing process for forming a metal pattern on a substrate according to an embodiment of the present invention. FIG. 2A-FIG. 2F are schematic top views showing process steps of a manufacturing process for forming a metal pattern on a substrate according to an embodiment of the present invention.

Referring to FIG. 1 and FIG. 2A, firstly, Step S10 is performed, in which a plastic substrate 100 having at least one metal component 102 is provided. The surface 100a of the plastic substrate 100 has an opening S, and a portion 102P of the metal component 102 is exposed. The plastic substrate may be any substrate or device having a plastic material, and the plastic substrate can be three-dimensional, plate-shaped or a curved surface.

Next, Step S12 is performed. Please refer to FIG. 2B, a surface passivation treatment 20 is performed to the metal component 102. The surface passivation treatment 20 is mainly performed to the portion (the metal component exposing portion) 102P of the metal component 102 exposed through the opening S. The surface passivation treatment 20 can be, for instance, performed by immersing the plastic substrate 100 having the metal component 102 into an acidic solution Sa, so that an anti-plating coating 102a can be formed on the passivated metal component 102. Alternatively, the metal component 102 may be immersed in the acidic solution Sa to form the anti-plating coating 102a before being disposed into the plastic substrate 100. The acidic solution is an acidic solution with oxidizing capability, such as sulfuric acid/hydrogen peroxide solution, nitric acid solution, citric acid solution and phosphoric acid solution. The acidic solution may be, for instance, a 4 wt %˜80 wt % piranha solution, an aqueous solution containing 4 wt %˜55 wt % nitric acid, an aqueous solution containing 4 wt %˜10 wt % citric acid, or an aqueous solution containing 5 wt %˜15 wt % phosphoric acid. The surface passivation treatment includes immersing the metal component 102 in the acidic solution at 20° C.˜80° C. for a duration ranging from 30 seconds to 120 minutes, alternatively, 1 to 30 minutes, and then the treatment is completed. Step S12 may further include an ultrasonic cleaning, an NaOH degreasing, and an acidic solution neutralization process.

Note that the Step S10 and the Step S12 illustrated in FIG. 1 can be exchanged according to other embodiments of the present invention. That is, performing the surface passivation treatment 20 of Step S12 to a specific metal component first, and then encapsulating, assembling, disposing, or placing the metal component into the substrate 100 by either insert moulding, hot melting, or other well-known plastic material processing techniques. Additionally, the metal component can also be assembled into the plastic substrate by embedding, inserting or fitting.

The plastic substrate 100 can be an electronic device substrate or a casing, or, a casing or a printed circuit board of a portable device such as a mobile phone. In addition, the substrate can be, but not limited to, plate-shaped, three-dimensional or a curved surface. The metal component 102 can be a metal insert, a locking device or other devices having certain functions disposed on the substrate. For example, the component 102 can be a metal nut or a metal sheet. The metal sheet illustrated in FIG. 2A-2F may be, but not limited to, a backboard with functions like structural reinforcement, anti-magnetic or weight gaining The material of the metal component 102 may be stainless steel or stainless steel containing chromium-nickel (Cr—Ni), such as SUS430 stainless steel or SUS304 stainless steel.

Taking the stainless steel containing chromium-nickel as an example of the aforementioned surface passivation treatment, firstly, the metal component 102 is immersed in an acidic solution, in which the acidic solution is able to dissolve iron oxide contained in the stainless steel material and enrich the chromium content of the treated surface. Then the surface chromium is oxidized and a passivating layer (chromium oxide enriched layer) is formed on the surface of the stainless steel. Such passivating layer (chromium oxide enriched layer) coated on the surface of the metal component 102 constitutes the aforementioned anti-plating coating 102a. As for the chromium oxide enriched layer, or the chromium oxide layer, the content of chromium oxide in such layer is at least more than three times, alternatively 13 times, to the content of chromium (i.e. the content of chromium oxide/the content of chromium≧3, alternatively≧13).

For the following experiment, stainless steel containing chromium-nickel is used as an example of the material of the metal component. The test sheets of SUS304 stainless steel and SUS430 stainless steel are immersed in a 4 wt %˜80 wt % piranha solution or an aqueous solution containing 5 wt %˜55 wt % nitric acid at 60° C. for about 25 minutes. As a result, the test sheets of these two stainless steel materials remain unplated for 4 hours, namely, the anti-plating effect lasted for 4 hours, even than being immersed in a strong alkaline copper plating solution. After the full plating processes of copper, nickel and gold in sequence, no metal is deposited on any of the passivated test sheets. After removing the surface oxide layer physically by a polishing process following by a treatment of oxidizing acidic solution and alkaline wash by using NaOH, the SUS304 stainless steel test sheet and SUS430 stainless steel test sheet still remain unplated even than being immersed in the copper plating solution.

Therefore, the surface of the metal component is passivated by the surface passivation treatment and protected by the anti-plating coating. In the following electroless plating process(es) (including the copper electroless plating process, nickel electroless plating process and/or gold electroless plating process), the anti-plating capability persists for at least 4 hours thereby achieving an excellent anti-plating effect.

So far, the metal component 102 on the plastic substrate 100 has been passivated and protected by the anti-plating coating 102a. Hence, in the following processes of electroless plating, locations or regions other than the passivated region of the plastic substrate 100 may be plated, whereas the metal component 102 protected by the anti-plating coating 102a will not be reacted with the electroless plating solution and therefore no metal layer will be formed thereon.

Referring to FIG. 1 and FIG. 2C, in which Step S14 is performed. A laser preliminary treatment is conducted to a predetermined region A of the plastic substrate 100 to form an activated seed layer 204.

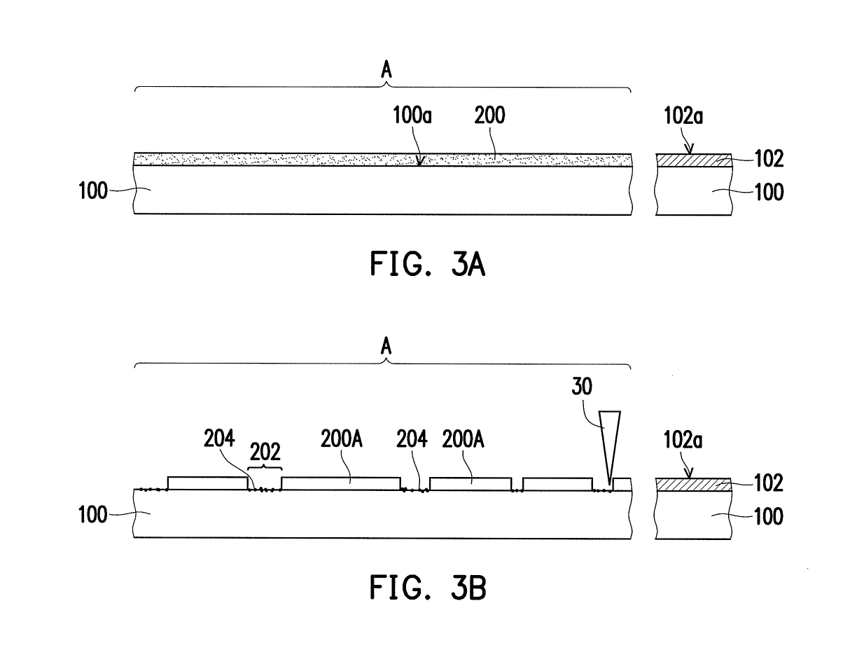

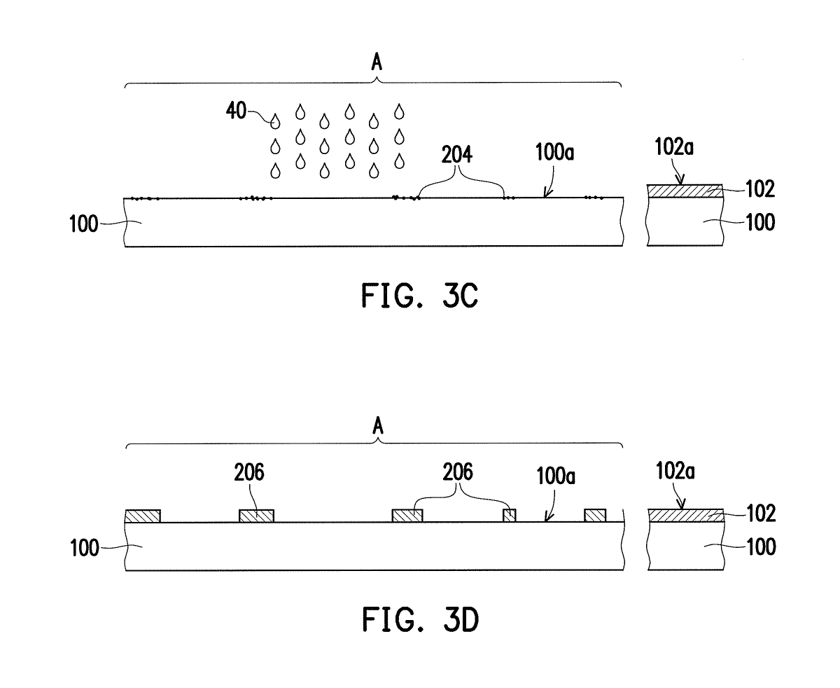

According to an embodiment of the present invention, the laser preliminary treatment may include a step of applying laser direct structuring (LDS) technology to the predetermined region A of the plastic substrate 100. The following detailed mechanism will be set forth by taking laser direct structuring technology as an example. FIG. 3A-3D are schematic cross-sectional views showing process steps of a manufacturing process for forming a metal pattern on a substrate. Referring to FIG. 3A, a mixture layer 200 is formed on the surface 100a of the plastic substrate 100 in the predetermined region A. The predetermined region A can be a peripheral region of the plastic substrate 100, and it can also be any region other than the region where the metal component is to be disposed. The mixture layer 200 may be formed by using, for instance, LDS-use plastic materials (including LDS catalyst). Or, the mixture layer 200 may include other laser activating materials, such as metal nano particles or metallic nano particles, etc. As shown in the right-hand side of FIG. 3A, the anti-plating coating 102a is formed on the metal component 102 on the plastic substrate 100 due to the surface passivation treatment. This region is not participated in the following electroless plating process, so, the laser preliminary treatment does not need to be performed to the region; it is illustrated for comparison purpose only. Referring to FIG. 3B, the laser step 30 is performed to treat a portion of the mixture layer 200, in order to form the activated seed layer 204. The distribution range of the activated seed layer 204 (that is, the location of the laser treated region 202) corresponds to the location where the metal pattern is to be formed during the following process. Correspondingly, the portion of the mixture layer not treated by laser (the untreated portion of the mixture layer) is labeled as 200A. The laser used in the laser step may be infrared ray (IR) laser with a wavelength of 1064 nm.

In the laser irradiation process, the laser activating material in the mixture layer 200 fuses and turns into the activated seed layer 204 in the laser step 30. In addition, the activated seed layer 204 is tightly attached to the surface 100a. The activated seed layer 204 distributed within the laser treated region 202 can function as the seed layer in the following electroless plating process. Since the formation of the activated seed layer 204 is conducted by laser activation, the position and the shape of the subsequently formed metal pattern can be precisely controlled.

Please refer to FIG. 3C, following the laser step 30, the cleaning step 40 is performed to remove the residual portions of the mixture layer (the untreated portion of the mixture layer) 200A, so as to expose the surface 100a of the plastic substrate 100. The activated seed layer 204 is remained on the surface 100a of the plastic substrate 100 after the cleaning step 40. The solvent used in the cleaning step 40 may be water, acetone, or other appropriate alcohols.

Referring to FIG. 1, FIG. 2D and FIG. 3D, the electroless plating process is then performed on the plastic substrate 100 (see step S16). Moreover, a first electroless plating process is performed to the plastic substrate 100. Because the activated seed layer 204 is formed on the laser pre-treated region within the predetermined region A and on the plastic substrate 100, a metal pattern 206 is formed on the surface 100a of the plastic substrate 100 within the predetermined region A by performing the electroless plating process on the activated seed layer 204 remained on the surface 100a of the plastic substrate 100. In this embodiment, the activated seed layer 204 functions as the seed pattern for electroless plating, therefore the metal pattern 206 can be precisely formed over the distribution range of such activated seed layer 204.

The process step described in FIG. 3D is equivalent to the first electroless plating process shown in FIG. 2D. Taking copper electroless plating process as an example of the first electroless plating process, the metal pattern 206 formed may have a copper pattern with a thickness of, for instance, no more than 20 μm. As for the portion protected by the anti-plating coating 102a (as shown in the right-hand side of FIG. 3D), no electroless plating reaction occurs, and the activated seed layer 204 and the metal pattern 206 can be seen as an integral body. The metal pattern 206 may be a continuous pattern or non-continuous patterns.

By using laser, the formed metal pattern may have a very precise outline or border. In addition, the laser scanning can correspond to various types of configurations, profiles or structures of the substrate, so that the metal pattern may be precisely formed on an planar surface or an uneven object.

Please refer to FIG. 2E-2F, a second electroless plating process and a third electroless plating process are subsequently performed to form a first metal layer 208 and a second metal layer 210 in sequence in the predetermined region A of the plastic substrate 100 and over the metal pattern 206. Taking copper electroless plating, nickel electroless plating, and gold electroless plating process as examples of the first electroless plating process, the second electroless plating process and the third electroless plating process, respectively. As a result, the first metal layer 208 may form a nickel pattern and the second metal layer 210 may foam a gold pattern.

The method for forming a metal pattern described in the aforementioned embodiment can be used for forming a substrate as well. The substrate includes at least one metal component and a metal pattern formed on the substrate within a predetermined region. The substrate has at least one opening S, and the metal component 102 is exposed through the opening S. The metal component has an anti-plating coating fowled by conducting a surface passivation treatment, where the metal component is immersed into an acidic solution. The metal pattern is formed by performing at least one electroless plating process. Again, the metal component protected by the anti-plating coating will not be plated during the electroless plating process.

In this embodiment, a metal pattern can be formed on a plastic substrate by electroless plating. The metal pattern set forth in this disclosure can be a metal antenna pattern with multiple conductive layers as an example. After forming a copper pattern (or layer) having good conductivity on the substrate, an anti-scratch nickel layer is formed on the copper pattern, and then a gold layer is formed on the nickel layer to reduce oxidation of the nickel layer. Nonetheless, the invention is not limited to the aforementioned embodiments. The metal pattern may also be formed as a single conductive layer. The metal pattern can be an antenna structure, a contact pad or other metal components, and the material of the metal pattern can be as copper, nickel, cold, silver or any combination of the above.

Specifically, the plastic substrate 100 may be immersed in the electroless plating solution during the electroless plating to form the metal pattern. Meanwhile, because the metal component 102 of the plastic substrate 100 is protected by the anti-plating coating 102a, any plating on the metal material is prevented. No metal material will be plated on the anti-plating coating 102a formed on the metal component 102, therefore achieving the aspect of anti-plating. By doing so, the electroless plating solution will not be wasted, the cost is further saved and the functional or cosmetic defects caused by the formation of unexpected metal layer are forestalled. Besides, the metal pattern can be selectively formed in the predetermined region during the electroless plating process by the passivation treatment, so that the failure rate of the product can be significantly lowered, thereby giving better economic benefits.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming a metal pattern, comprising:
providing a substrate having at least one metal component and at least one opening exposing at least a portion of the metal component;
performing a surface passivation treatment to the metal component;
performing a laser preliminary treatment to a predetermined region of the substrate to form an activated seed layer; and
performing an electroless plating process on the activated seed layer in the predetermined region of the substrate to form a metal pattern.

2. The method for forming a metal pattern according to claim 1, wherein the surface passivation treatment comprises immersing the metal component in an acidic solution to foam an anti-plating coating on the metal component.

3. The method for forming a metal pattern according to claim 2, wherein the acidic solution is an aqueous solution containing 4 wt %˜55 wt % nitric acid, an aqueous solution containing 4 wt %˜10 wt % citric acid or an aqueous solution containing 5 wt %˜15 wt % phosphoric acid, and the surface passivation treatment comprises immersing the metal component in the acidic solution at 20° C.˜80° C. for 30 seconds˜120 minutes.

4. The method for forming a metal pattern according to claim 2, wherein the acidic solution is 4 wt %˜80 wt % piranha solution, an aqueous solution containing 4 wt %˜10 wt % citric acid or an aqueous solution containing 5 wt %˜15 wt % phosphoric acid, and the surface passivation treatment includes immersing metal component in the acidic solution at 20° C.˜80° C. for 30 seconds˜120 minutes.

5. The method for forming a metal pattern according to claim 2, wherein the anti-plating coating is a passivating layer containing chromium oxide and chromium, wherein the content of chromium oxide is at least three times higher than the content of chromium of the passivating layer.

6. The method for forming a metal pattern according to claim 1, wherein the electroless plating process is a copper electroless plating process, and the metal pattern is a copper pattern.

7. The method for forming a metal pattern according to claim 1, wherein the electroless plating process includes a copper electroless plating process, a nickel electroless plating process and a gold electroless plating process, and the metal pattern is a copper pattern covered by a nickel layer and a gold layer.

8. A substrate structure, comprising;
a substrate, having at least one opening;
at least one metal component located in the substrate, wherein the metal component includes at least one exposed portion exposed through the at least one opening, and the at least one exposed portion has an anti-plating coating having chromium oxide and chromium, wherein the content of chromium oxide is at least three times higher than the content of chromium; and
a metal pattern located in a predetermined region of the substrate and on the substrate.

9. The substrate structure according to claim 8, wherein the metal pattern is a copper pattern.

10. The substrate structure according to claim 8, wherein the metal pattern is a copper pattern covered by a nickel layer and a gold layer.
